(19) United States
(12) Patent Application Publication
(10) Pub. No.: US 2005/0274961 A1
(43) Pub. Date: Dec. 15, 2005

(54) Organic electroluminescent device and manufacuring method thereof

(76) Inventor: Chung-Yeh Iou, Wuci Township (TW)

Correspondence Address: RABIN & Berdo, PC, 1101 14TH STREET, NW, SUITE 500, WASHINGTON, DC, 20005, US

(21) Appl. No.: 11/005,013

(22) Filed: Dec. 7, 2004

(30) Foreign Application Priority Data
Jun. 11, 2004 (TW) 93116946

(51) Int. Cl. H01L 21/00; H01L 29/08; H01L 35/24; H01L 51/00; H01L 27/15; G03G 15/02

(52) U.S. Cl. 257/82; 438/22

(57) ABSTRACT

An organic electroluminescent device comprises an anode, a hole injection layer as CFx formed on the anode, a first hole transport layer formed on the hole injection layer and the first hole transport layer doped with a P-type dopant, a second hole transport layer formed on the first hole transport layer, a light emitting layer formed on the second hole transport layer, an electron transport layer formed on the light emitting layer, and a cathode formed on the electron transport layer. According to the structure of the organic electroluminescent device disclosed in the present invention, the hole injection layer and the first hole transport layer provide the function of increasing the efficiency of the hole injection so as to improve the operating life and stability of the device.

This application claims the priority benefit of Taiwan Patent application Serial No. 93116946, filed Jun. 11, 2004, the subject matter of which is incorporated herein by reference.

### BACKGROUND OF THE INVENTION

1. Field of the Invention

The invention relates in general to an electroluminescent device and manufacturing method thereof, and more particularly to an organic electroluminescent device and manufacturing method thereof.

2. Description of the Related Art

Organic electroluminescent devices, such as organic light-emitting diodes (OLEDs), have been popularly applied to various flat displays because such advantages of self-emissive, very thin form factor, high luminance, high luminous efficiency, high contrast, fast response time, wide viewing angle, low power consumption, wide temperature operation range, and potential of flexible substrate.

The organic electroluminescent device has a multi-layers structure, and the emissive theory of OLED is about the injection of electrons and holes from metal cathode and transparent anode respectively, after recombining within an organic light emitting layer, the energy is then transferred into visible light. A hole injection layer and a hole transport layer are between the organic light emitting layer and the anode, and a electron transport layer is between the organic light emitting layer and the cathode. Therefore, such multi-layers structure is contributive to drive electrons moving from the cathode to the anode.

Mobility of holes is greater than that of electrons in the OLED; however, electric charges are accumulated inside the device by such electric unbalance so that the stability of the device is greatly affected. Excessive electric charges accumulated inside the device will shorten the life-time of the device, and conventionally, increasing the thickness of the hole transport layer improves the stability of the device by allowing holes and electrons combining in the organic light emitting layer at the same period. However, increasing the thickness of the hole transport layer increases driving voltage of the device and decreases the efficiency and the life-time of the device.

### SUMMARY OF THE INVENTION

It is therefore an object of the invention to provide an organic electroluminescent device and a manufacturing method thereof. The organic electroluminescent device of the present invention can maintain the stability of a driver voltage with a long period and have good stability and long operating life.

The invention achieves the above-identified object by providing an organic electroluminescent device comprising an anode, a hole injection layer formed on the anode, a first hole transport layer doped with a P-type dopant formed on the hole injection layer, a second hole transport layer formed on the first hole transport layer, a light emitting layer formed on the second hole transport layer, an electron transport layer formed on the light emitting layer, and a cathode formed on the electron transport layer.

Also, the invention achieves the above-identified object by providing a manufacturing method of an organic electroluminescent device, comprising the steps of: providing a substrate and forming an anode on the substrate; forming a hole injection layer on the anode; forming a first hole transport layer on the hole injection layer, and the first hole transport layer is doped with a P-type dopant; forming a second hole transport layer on the first hole transport layer; forming a light emitting layer on the second hole transport layer; forming an electron transport layer on the light emitting layer; and forming a cathode on the electron transport layer. According to the invention, the hole injection layer and the first hole transport layer provide the function of increasing the stability of the organic electroluminescent device.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a schematic view of an organic electroluminescent device according to the embodiment of the present invention.

FIG. 2A is a schematic view of the organic electroluminescent device A according to the experiment of the present invention.

FIG. 2B is a schematic view of the organic electroluminescent device B according to the experiment of the present invention.

FIG. 3 is a graph showing the relation between relative luminescence and operation time of organic electroluminescent devices A, B and C.

FIG. 4 is a graph showing the relation between voltages and operation time of organic electroluminescent devices A, B and C.

### DETAILED DESCRIPTION OF THE INVENTION

The chief concept of the present invention is using a hole injection layer and a hole transport layer doped with a P-type dopant to improve the stability of the organic electroluminescent device. There will be an experiment including two comparisons in the following description to clarify the present invention, but it is necessary to understand that it is not limited the present invention.

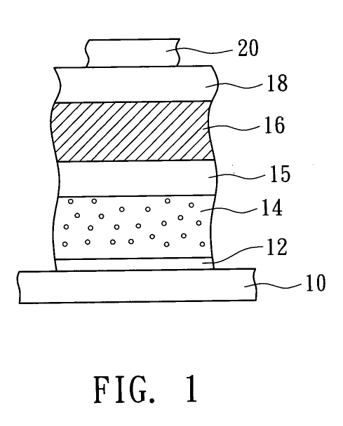

Referring to FIG. 1, it is a schematic view of an organic electroluminescent device according to the preferred embodiment of the present invention. An organic electroluminescent device includes an anode 10, a hole injection layer 12 formed on the anode 10, a first hole transport layer 14 formed on the hole injection layer 12 and the first hole transport layer 14 doped with a P-type dopant, a second hole transport layer 15 formed on the first hole transport layer 14, a light emitting layer 16 formed on the second hole transport layer 15, an electron transport layer 18 formed on the light emitting layer 16, and a cathode 20 formed on the electron transport layer 18. The hole injection layer 12 possesses ability of increasing hole injection, and the first hole transport layer 14 doped with the P-type dopant provides ability of attracting electrons and both operate in coordination to maintain the stability of drive voltage and to improve the operating life and stability of the device.

The material of the hole injection layer 12 includes porphorinic compounds, phthalocyanines or preferred CFx compounds. The material of the first hole transport layer 14 is a diamine derivative doped with a P-type dopant. The diamine derivative, for example, is
N,N-bis-(1-naphthyl)-N,N-diphenyl-1,1-biphenyl-4,4-diamine (NPB, sold by Kodak Corp.),
N,N′-diphenyl-N,N′-bis(3-methylphenyl)(1,1′-biphenyl)-4,4′-diamine (TPD, sold by Kodak Corp.) or 4,4′,4″-tris(2-naphthylphenylamino)triphenyl-amine (2T-NATA, sold by Kodak Corp.). The P-type dopant is preferably tetra(fluoro)-tetra(cyano)quinodimethane (TF-TCNQ).

The material of the light emitting layer 16 includes Tris-(8-hydroxyquinoline)aluminium (Alq3, sold by Kodak Corp.), N,N-bis-(1-naphthyl)-N,N-diphenyl-1,1-biphenyl-4,4-diamine (NPB, sold by Kodak Corp.), 1H,5H,11H-1-benzopyrano-6,7,8-ij-quinolizin-11-one, and 10-(2-benzothiazolyl)-2,3,6,7-tetrahydro-1,1,7,7-tetramethyl-(9Cl) (C545T, sold by Kodak Corp.).

1) The materials of red light emitting layer can be
Red Host: 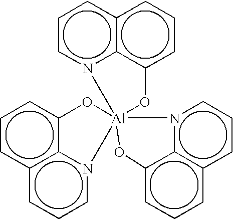
Tris-(8- hydroxyquinoline)aluminium (Alq3, sold by Kodak Corp.) 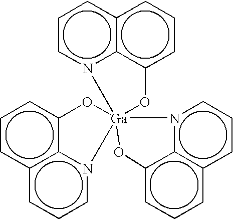
tris(8-hydroxyquinolinolatl)gallium (Gaq3)
Red dopant: 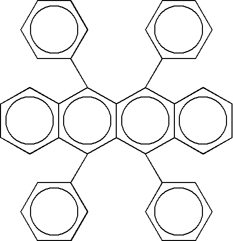
rubrene (Rurene, sold by Kodak Corp.) 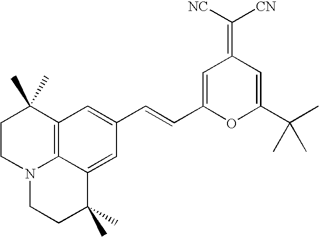
4-(dicyanomethylene)-2-t-butyl-6-(1,1,7,7-tetramethyljulolidyl-9-enyl)-4H-pyran (DCJTB sold by Kodak Corp.)

2) The materials of green light emitting layer can be Green Hosts can be the same as red hosts.
Green dopant: 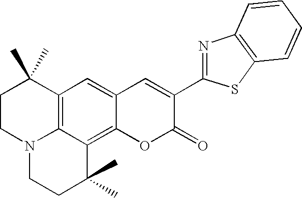
10-(2-benzothiazolyl)-1,1,7,7-tetramethyl −2,3,6,7-tetrahydro-1H,5H, 11H-benzo[l]pyrano[6,7,8-ij]quinolizin-11-one (C545T sold by Kodak Corp.)

3) The materials of blue light emitting layer can be
Blue Host: 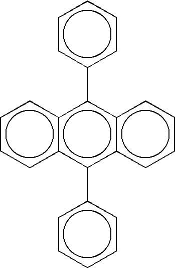
9,10-di(phenyl)anthracene (DPA) 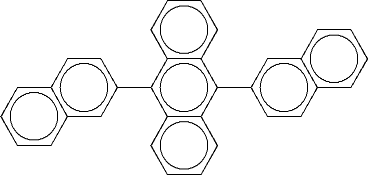
9,10-di(2-naphthyl)anthracene (ADN, sold by Kodak Corp.)
Blue dopant: 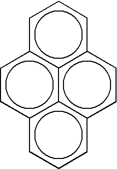
pyrene 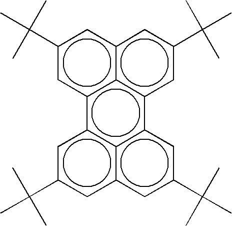
2,5,8,11-tetra(tert-butyl) -perylene (TBP, sold by Kodak Corp.)

The material of the electron transport layer 18 can be Tris-(8-hydroxyquinoline)aluminium (Alq3, sold by Kodak Corp.).

The anode 10 is formed by evaporating an indium tin oxide (ITO) layer on a substrate. The cathode 20 consists of lithium fluorine (LiF) and aluminum (Al).

A manufacturing method for the organic electroluminescent device includes the following steps. First, a substrate is provided, such as a glass substrate evaporated with ITO, and processed by oxygen plasma (O₂ plasma) or UV ozone so as to form the anode 10 on the substrate. Next, a hole injection layer 12, capable of increasing the ability of injecting holes, is evaporated on the anode 10. The thickness of the hole injection layer 12 ranges from 5 Å to 1000 Å. The hole injection layer 12 includes carbon fluorine (CFx) compounds, and the thickness of the CFx compounds ranges from 5 Å to 500 Å, and preferably less than 100 Å. Then, a first hole transport layer 14, doped with a P-type dopant, is formed on the hole injection layer 12. The P-type dopant of the first hole transport layer is at the concentration of 0.1 wt % to 50 wt %. The material of the first hole transport layer 14 is preferably a composition of NPB and TF-TCNQ ([NPB:TF-TCNQ]), and a thickness of the first hole transport layer 14 ranges from 500 Å to 5000 Å. Further, a second hole transport layer 15 is formed on the first hole transport layer 14, and the thickness of the second hole transport layer 15 ranges from 50 Å to 500 Å. A light emitting layer 16 is formed on the second hole transport layer 15. The material of the light emitting layer 16 can be, for example, a composition of Alq3 and rubrene and DCJTB([Alq3:rubrene:DCJTB]) suitable for red light, a composition of Alq3 and NPB and C545T ([Alq3:NPB:C545T]) suitable for green light, or a composition of ADN and B52 ([ADN:B52]) suitable for blue light. An electron transport layer 18 is formed on the light emitting layer 16, and finally, a cathode 20 is formed on the electron transport layer 18 by evaporating a lithium-fluorine (LiF) layer on the electron transport layer 18 and an aluminum (Al) layer on the LiF layer.

### Relative Experiments

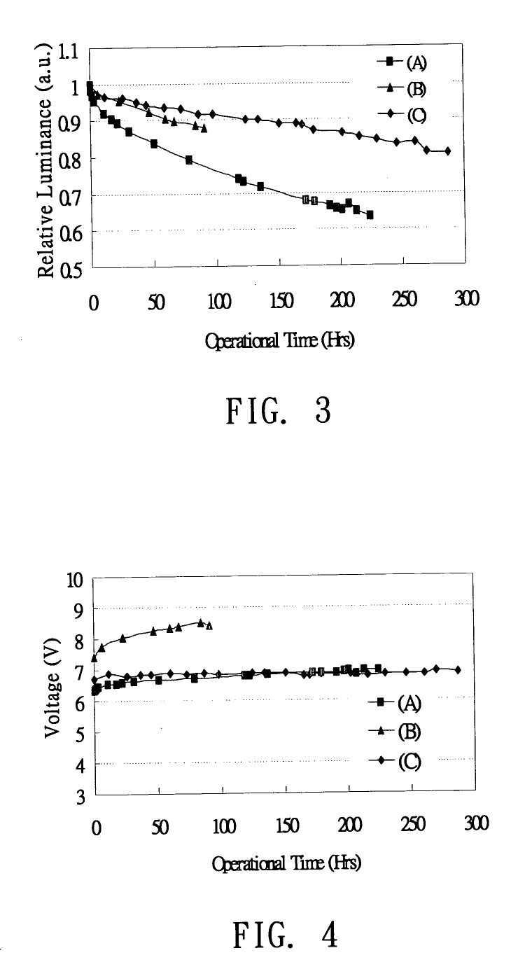

A preferred device C and two comparison device, A and B, are presented below, and the experimental procedures are shown as follow. Also, the results are shown in FIG. 3 and FIG. 4. FIG. 3 is a graph showing the relation between relative luminescence and operation time of organic electroluminescent devices A, B and C. FIG. 4 is a graph showing the relation between voltages and operation time of organic electroluminescent devices A, B and C.

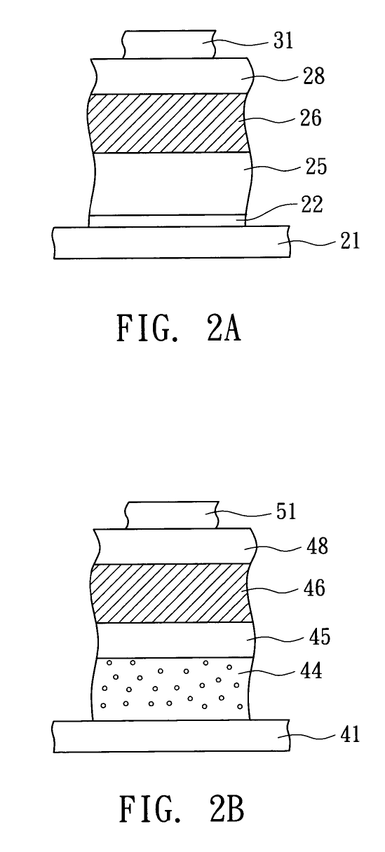

Referring to FIG. 2A, it is a schematic view of the organic electroluminescent device according to a comparison device A in the comparative experiment of the present invention. An indium tin oxide (ITO) glass substrate is provided and then an anode 21 is formed by UV ozone. Next, a carbon fluorine compound (CFx) thin film is formed on the anode 21 by plasma deposition as a hole injection layer 22. Then, a NPB is evaporated on the hole injection layer 22 as a hole transport layer 25, and the thickness of the hole transport layer 25 is about 80 nm. An organic light emitting layer 26, consisting of Alq3, NPB and C545T, is formed on the hole transport layer 25. The composition ratio of material in the organic light emitting layer 26 is [Alq3:NPB]: C545T=[0.5:0.5]:1%., and the thickness of the organic light emitting layer 26 is about 60 nm. Further, an electron transport layer 28 is formed on the organic light emitting layer 26 by evaporating Alq3 with the thickness of 20 nm. Finally, a lithium-fluorine (LiF) layer with the thickness of 0.1 to 1.0 nm n the electron transport layer 28 and an aluminum (Al) layer with the thickness of 100 nm are evaporated on the LiF layer to form the cathode 31. Therefore, the comparison device A of the comparative experiment can be presented as an abbreviated formula:
ITO/CFx/NPB(80 nm)/[Alq3:NPB):C545T=[0.5:0.5]:1%(60 nm)/Alq3(20 nm)/LiF(1.0 nm)/Al(100 nm)

In addition, the comparison device A manufactured is symbolized by a code (A) in FIG. 3 and FIG. 4.

Referring to FIG. 2B, it is a schematic view of the organic electroluminescent device B according to the comparative experiment of the invention. The organic electroluminescent device B includes an anode 41, a first hole transport layer 44, a second hole transport layer 45, a light emitting layer 46, an electron transport layer 48, and a cathode 51. The differences between the comparison devices A and B are listed below:

1. There is no a carbon fluorine compound (CFx) thin film formed on the anode 41 so that the comparison device B has no hole injection layer 22 compared to the comparison device A.

2. NPB with the thickness of about 150 um is evaporated on the anode 41 to form the first hole transport layer 44, additionally, a 2.0% TF-TCNQ is doped therein.

3. After the first hole transport layer 44 doped with a 2.0% TF-TCNQ is formed, another NPB with a thickness of 20 nm is evaporated on the first hole transport layer 44 to form a second hole transport layer 45.

Therefore, the comparison device B can be presented as an abbreviated formula:
ITO/NPB:2%TF-TCNQ(150 nm)/NPB(20 nm) [Alq3:NPB]:C545T=[0.5:0.5]:1%(60 nm)/Alq3(20 nm)/LiF(1.0 nm)/Al(100 nm)

In addition, the comparison device B manufactured in the comparative experiment is symbolized by a code (B) in FIG. 3 and FIG. 4.

### Preferred Embodiment

Referring to FIG. 1, it is a schematic view of an organic electroluminescent device according to the preferred embodiment of the present invention. An indium tin oxide (ITO) glass substrate is formed by oxygen plasma (O₂ plasma) and an anode 10 is formed. Next, a carbon fluorine (CFx) compound thin film is formed on the anode 10 by plasma deposition as a hole injection layer 12. Then, a NPB with the thickness of 150 nm and doped with 2.0% TF-TCNQ, is evaporated on the hole injection layer 12 as a first hole transport layer 14. Next, a second hole transport layer 15 with the thickness of about 100 to 500 Å is formed on the first hole transport layer 14 by evaporating a NPB with the thickness of 20 nm and doping with 2.0% TF-TCNQ. Then, an organic light emitting layer 16, consisting of Alq3, NPB and C545T, is formed on the hole transport layer 15. The composition ratio of material in the organic light emitting layer 16 is [Alq3:NPB]: C545T=[0.5:0.5]:1%., and the thickness of the organic light emitting layer 16 is about 60 nm. Further, an electron transport layer 18 is formed on the organic light emitting layer 16 by evaporating Alq3 with a thickness of 20 nm. Finally, a lithium-fluorine (LiF) layer with the thickness of 1.0 nm evaporated on the electron transport layer 18 and an aluminum (Al) layer with the thickness of 100 nm evaporated on the LiF layer are form the cathode 20. Therefore, the preferred device C in the preferred embodiment of the present invention can be presented as an abbreviated formula:
ITO/CFx/NPB:2%TF-TCNQ(150 nm)/NPB(20 nm]/[Alq3:NPB]:C545T=[0.5:0.5]:1%(60 nm)/Alq3(20 nm)/LiF(1.0 nm)/Al(100nm)

In addition, the preferred device C in the preferred embodiment of the present invention is symbolized by a code (C) in FIG. 3 and FIG. 4.

FIG. 3 indicates that the original brightness of the comparison device A is 2000 nits at the beginning, and the brightness is reduced to 1200 nits after 250 hours of operation, which declines for 40 percents; the original brightness of the comparison device B is 2000 nits at the beginning, and the brightness is reduced to 1700 nits after 100 hours of operation, which declines for 15 percents; the original brightness of the comparison device C is 2000 nits at the beginning, and the brightness is reduced to 1600 nits after 300 hours of operation, which declines only for 20 percents. As the results indicated in FIG. 3, the organic electroluminescent device in the present invention, such as the comparison device C, having a hole injection layer 12 and a first hole transport layer 14 doped with P-type dopants can prolong the life time of the device effectively.

Further, according to the comparison results between the omparison device A and the comparison device B, it is indicated that the decline rate of the comparison device A is greater than that of the comparison device B and the preferred device C. The comparison device A has the hole injection layer 22 and the hole transport layer 25 without doping any dopants, while the comparison device B has the hole transport layer 44 doper with P-type dopants but no hole injection layer 12. The decline rate of the comparison device B is greater than that of the preferred device C, because the comparison device B lacks a hole injection layer 12 like the comparison device A does. Therefore, it is proved that a hole injection layer doped with P-type dopants does improve the life time of the organic electroluminescent device.

FIG. 4 indicates that the operating voltage difference of the comparison device A is less than 1V after 250 hours of operation; the operating voltage difference of the comparison device B is greater than 1V after 100 hours operation, and the operating voltage increases with the operational time; the operatingvoltage difference of the preferred device C is still less than 1V after 250 hours of operation. Because the comparison device A and the preferred device C respectively have the hole injection layers (CFx) 22 and 12, it demonstrates that the hole injection layer (CFx) can keep the operating voltage stable.

In conclusion, according to the structure of the organic electroluminescent device disclosed in the present invention, the hole injection layer (such as CFx) 12 and the first hole transport layer 14 doped with P-type dopants (such as TF-TCNQ) provide the function of increasing the efficiency of the hole injection 12 so as to improve the operating life and stability of the device.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An organic electroluminescent device comprising:
an anode;
a hole injection layer formed on the anode;
a first hole transport layer formed on the hole injection layer, wherein the first hole transport layer is doped with a P-type dopant;
a second hole transport layer formed on the first hole transport layer;
a light emitting layer formed on the second hole transport layer;
an electron transport layer formed on the light emitting layer; and
a cathode formed on the electron transport layer.

2. The organic electroluminescent device according to claim 1, wherein the hole injection layer comprises CFx compounds.

3. The organic electroluminescent device according to claim 1, wherein the thickness of the hole injection layer ranges from 5 Å to 1000 Å.

4. The organic electroluminescent device according to claim 1, wherein the first hole transport layer comprises a diamine derivative.

5. The organic electroluminescent device according to claim 4, wherein the diamine derivative is selected from the group consisting of N,N-bis-(1-naphthyl)-N,N-diphenyl-1,1-biphenyl-4,4-diamine(NPB), N,N′-diphenyl-N,N′-bis(3-methylphenyl)(1,1′-biphenyl)-4,4′-diamine (TPD) and 4,4′,4″-tris(2-naphthylphenylamino)triphenyl-amine (2T-NATA).

6. The organic electroluminescent device according to claim 1, wherein the P-type dopant comprises tetra(fluoro)-tetra(cyano)quinodimethane (TF-TCNQ).

7. The organic electroluminescent device according to claim 1, wherein the P-type dopant of the first hole transport layer is at the concentration of about 0.1 wt % to 50 wt %.

8. The organic electroluminescent device according to claim 1, wherein the first hole transport layer comprises NPB doped with TF-TCNQ.

9. The organic electroluminescent device according to claim 1, wherein the thickness of the first hole transport layer ranges from 500 Å to 5000 Å.

10. The organic electroluminescent device according to claim 1, wherein the thickness of the second hole transport layer ranges from 50 Å to 500 Å.

11. The organic electroluminescent device according to claim 1, wherein the light emitting layer comprises a host doped with a dopant selected from the group consisting of rubrene,
4-(dicyanomethylene)-2-t-butyl-6-(1,1,7,7-tetramethyljulolidyl-9-enyl)-4H-pyran, and
10-(2-benzothiazolyl)-1,1,7,7-tetramethyl-2,3,6,7-tetrahydro-1H,5H,11H-benzo [l]pyrano[6,7,8-ij]quinolizin-11-one.

12. The organic electroluminescent device according to claim 1, wherein the host is selected from the group consisting of Tris-(8-hydroxyquinoline)aluminium, and tris(8-hydroxyquinolinolatl)gallium.

13. The organic electroluminescent device according to claim 1, wherein the light emitting layer comprises a host doped with a dopant selected from the group consisting of pyrene, and 2,5,8,11-tetra(tert-butyl) -perylene.

14. The organic electroluminescent device according to claim 13, wherein the host is selected from the group consisting of 9,10-di(phenyl)anthracene, and 9,10-di(2-naphthyl)anthracene.

15. The organic electroluminescent device according to claim 1, wherein the electron transport layer comprises Tris-(8-hydroxyquinoline)aluminium (Alq3).

16. The organic electroluminescent device according to claim 1, wherein the cathode includes lithium fluorine (LiF), aluminum (Al) or the combination thereof.

17. A method for manufacturing an organic electroluminescent device, comprising:
providing a substrate;
forming an anode on the substrate;
forming a hole injection layer on the anode;
forming a first hole transport layer on the hole injection layer, wherein the first hole transport layer is doped with a P-type dopant;
forming a second hole transport layer on the first hole transport layer;
forming a light emitting layer on the second hole transport layer;
forming an electron transport layer on the light emitting layer; and
forming a cathode on the electron transport layer.

18. The method according to claim 17, wherein the step of forming the anode comprises performing an oxygen plasma (O₂ plasma) treatment.

19. The method according to claim 17, wherein the step of forming the anode comprises performing a UV ozone treatment.

20. The method according to claim 17, wherein the step of forming the hole injection layer on the anode comprises depositing a thin film of CFx compounds on the anode.

21. The method according to claim 17, wherein the step of forming the first hole transport layer on the hole injection layer comprises disposing a diamine derivative doped with the P-type dopant on the hole injection layer.

22. The method according to claim 17, wherein the step of forming the electron transport layer on the light emitting layer comprises evaporating a layer of Tris-(8- hydroxyquinoline)aluminium (Alq3) on the light emitting layer.

23. The method according to claim 17, wherein the step of forming the cathode on the electron transport layer comprises forming a lithium-fluorine (LiF) layer on the electron transport layer and forming an aluminum (Al) layer on the LiF layer.
